(19) United States
(12) Patent Application Publication
(10) Pub. No.: US 2006/0144565 A1
(43) Pub. Date: Jul. 6, 2006

(54) Heat dissipation devices and fabrication methods thereof

(75) Inventors: Hsin-Chang Tsai, Taoyuan Hsien (TW); Horng-Jou Wang, Taoyuan Hsien (TW); Darren Chen, Taoyuan Hsien (TW); Tai-Kang Shing, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/315,244

(22) Filed: Dec. 23, 2005

(30) Foreign Application Priority Data
Dec. 30, 2004 (TW) 93141432

(51) Int. Cl. H05K 7/20; F28D 15/02

(52) U.S. Cl. 165/104.26; 361/700; 165/104.33

(57) ABSTRACT

This invention id related to a heat dissipation device comprises a case having a heat dissipation path, a backflow path, a first link path, and a second link path for working fluid to circulate therein. The heat dissipation path and the backflow path are positioned in the different height levels individually. The working fluid will not be more easily have turbulence. The reduction of heat dissipation efficiency will be improved. And the working fluid will not be necessary to limit covering the liquid state and gaseous state both.

### BACKGROUND

The invention relates to heat dissipation devices and fabrication methods thereof, and in particular to a heat dissipation device and fabrication method thereof, wherein the heat dissipation device has paths for working fluid to circulate therethrough to dissipate heat.

Transistors per unit area on the electronic devices are currently becoming more and densely disposed. However, this inevitably increases heat. Accordingly, to keep devices within effective working temperatures, most methods conducted to dissipate heat utilize extra fans or heat sinks. Additionally, heat pipes can transmit heat across a considerable distance via small cross-section and temperature difference without requiring any additional power supply. Thus, under economic considerations of power supply and space utilization, heat pipes have become one of the most widely used heat dissipation devices.

As shown in FIG. 1, a heat pipe 1 comprises a case 10, a wick structure 16, and working fluid. While flowing in the vicinity of a first portion 100 of the case 10, the working fluid absorbs heat emitted from a heat source (not shown) and changes from a liquid state to a gaseous state. The working fluid, as shown by arrows 11 in FIG. 1, flows further toward a second portion 101 capable of heat dissipation and is immediately cooled and condensed to the original liquid state. Simultaneously, the working fluid adheres to the wick structure 16 located on the inner side of the housing 10. Through capillary attraction provided by the wick structure 16 redrawing the working fluid to the first portion 100, as shown by arrows 12 in FIG. 1, the working fluid can absorb heat and vaporize again. This thermal cycle generates a heat-transmitting direction 15 to the heat dissipation device 1.

The working fluid described in heat dissipation device 1 requires monitoring its working states. For example, since the working fluid transmits heat from the first portion 100 to the second portion 101 of the heat dissipation device 1 by utilizing changes between liquid and gaseous states. The heat dissipation device is limited by the housing of heat dissipation device 1 providing only space for working fluid circulating therein without limiting the flow direction of the working fluid. Further, the design may generate turbulence with only limited heat dissipation efficiency of the device. Thus, an improved heat dissipation device should be considered as an important subject in the future.

### SUMMARY

The invention provides a heat dissipation device comprising paths for working fluid circulating therein and dissipating heat.

The invention provides a heat dissipation device comprising a case having a first portion, a second portion and a working fluid. Moreover, a heat dissipation path is disposed in the vicinity of the second portion of the case, and a backflow path is disposed in the vicinity of the first portion of the case. A first link path connects one end of the heat dissipation path with one end of the backflow path and a second link path connects the other end of the heat dissipation path with the other end of the backflow path, wherein the working fluid absorbs heat while circulating through the backflow path and dissipates heat while circulating through the heat dissipation path.

A plane formed by the heat dissipation path is different from that formed by the backflow path.

The heat dissipation device comprises a partition disposed between the heat dissipation path and the backflow path.

The partition comprises dissipation space comprising a first dissipation path connected with the heat dissipation path as well as a second dissipation path connected with the backflow path.

The partition comprises dissipation space comprising a third dissipation path connected with the first link path as well as a fourth dissipation path connected with the second link path.

The second link path is annularly disposed outside the first link path.

The working fluid flows through the backflow path, the first link path, the heat dissipation path, the second link path in this order and finally back to the backflow path.

The case is of metal or nonmetal materials.

The invention provides a method for fabricating a heat dissipation device comprising forming a heat dissipation path, a backflow path, a first link path, and a second link path on a board, and bending and fixing the board with a bending line disposed to form a heat dissipation device.

The invention provides a method for fabricating a heat dissipation device, comprising forming a heat dissipation path, a first link path, and a second link path on a first board, forming a backflow path, a first link path, and a second link path on a second board, and gluing and fixing the side of the first board having the heat dissipation path with the side of the second board having the backflow path to form a heat dissipation device.

After bending and fixing the board or gluing and fixing the boards, the heat dissipation path and the backflow path are interactively independent.

Before bending and fixing the board or gluing and fixing the boards, a partition is disposed between the heat dissipation path and the backflow path and after bending and fixing the board, the heat dissipation path and the backflow path are interactively independent.

The heat dissipation path, the backflow path, the first link path, and the second link path are formed simultaneously.

The heat dissipation path comprises a plurality of recessions and a plurality of protrusions arranged in sequence and the backflow path also comprises a plurality of recessions and a plurality of protrusions arranged in sequence; when the board is bent (or glued) and fixed, the protrusions of the heat dissipation path are received in the corresponding recessions of the backflow path and the protrusions of the backflow path are received in the corresponding recessions of the heat dissipation path in order to form the heat dissipation device.

The recessions are complementary to the protrusions.

The protrusions comprise hooks and the recessions comprise grooves and while the protrusions of the heat dissipation path are received in the corresponding recession portions of the backflow path, the hooks of the protrusions joint the grooves of the recessions to bend and fix the board to form the heat dissipation device.

The protrusions comprise hooks and the recessions comprise grooves and while the protrusions of the backflow path are received in the corresponding recessions of the heat dissipation path, the hooks of the protrusions joint the grooves of the recessions to bend and fix the board to form the heat dissipation device.

The shapes of the recessions and the protrusions are trapezoid, rectangle, triangular, circular, or irregular.

Formation of the heat dissipation path, the backflow path, the first link path, and the second link path is accomplished by molding, punching, MEMS, etching, or other conventional means such as drilling, milling, digging or a combination thereof.

### DESCRIPTION OF THE DRAWINGS

The invention can be more fully understood by reading the subsequent detailed description and examples with references made to the accompanying drawings, wherein:

FIG. 1 is a cross section of a conventional heat dissipation device;

FIG. 2A is a top-viewed cross section of an embodiment of a heat dissipation device of the present invention;

FIG. 2B is a side-viewed cross section of an embodiment of a heat dissipation device of the present invention;

FIG. 2C is a cross section along A-A′ line in FIG. 2A;

FIG. 2D is a cross section of another embodiment of a heat dissipation device of the present invention;

FIG. 2E is a cross section along A-A′ line in FIG. 2A;

FIG. 2F is a cross section of another embodiment of a heat dissipation device of the present invention;

FIG. 2G is a cross section along A-A′ line in FIG. 2A;

FIG. 3A-3D are cross sections of various heat dissipation paths of the present invention;

FIG. 4A is a three-dimensional diagram of a fabrication method of a heat dissipation device of the present invention;

FIG. 4B is a three-dimensional diagram of another fabrication method of a heat dissipation device of the present invention;

FIG. 5A is a side-viewed cross section of an embodiment of accomplishing a heat dissipation device of the present invention;

FIG. 5B is a side-viewed cross section of an embodiment of accomplishing a heat dissipation device of the present invention along A-A′ line in FIG. 2A;

FIG. 5C is a side-viewed cross section of an embodiment of accomplishing another heat dissipation device of the present invention;

FIG. 5D is a side-viewed cross section of an embodiment of accomplishing another heat dissipation device of the present invention along A-A′ line in FIG. 2A;

FIG. 5E is a side-viewed cross section of an embodiment of accomplishing another heat dissipation device of the present invention along A-A′ line in FIG. 2A; and

FIG. 5F is a side-viewed cross section of an embodiment of accomplishing another heat dissipation device of the present invention along A-A′ line in FIG. 2A.

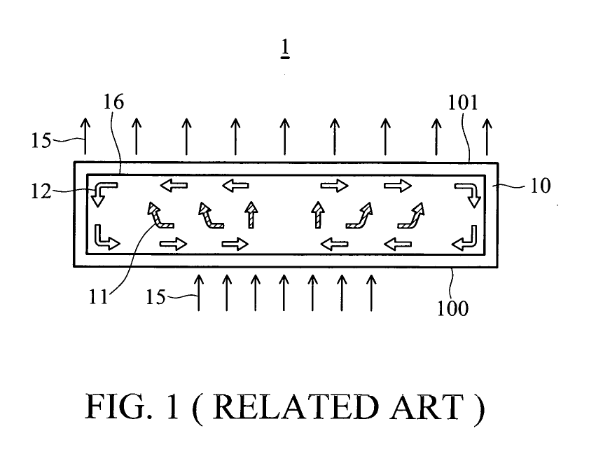

### DETAILED DESCRIPTION

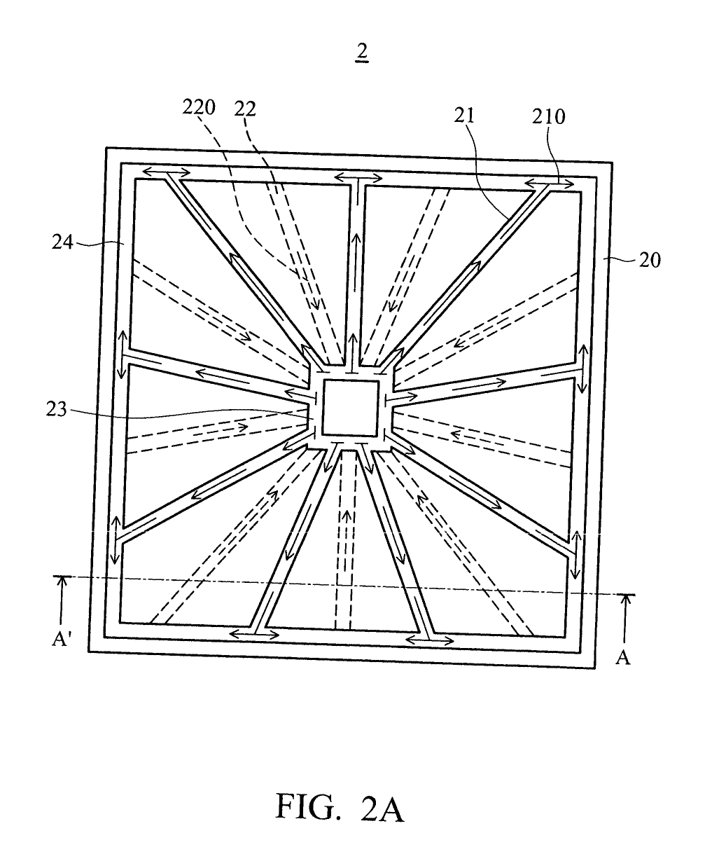

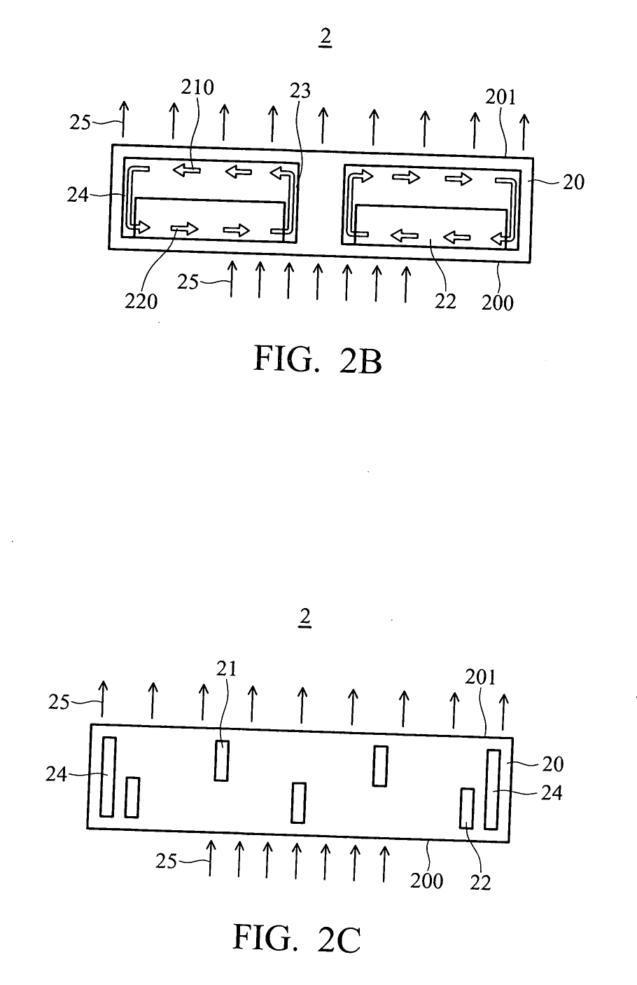

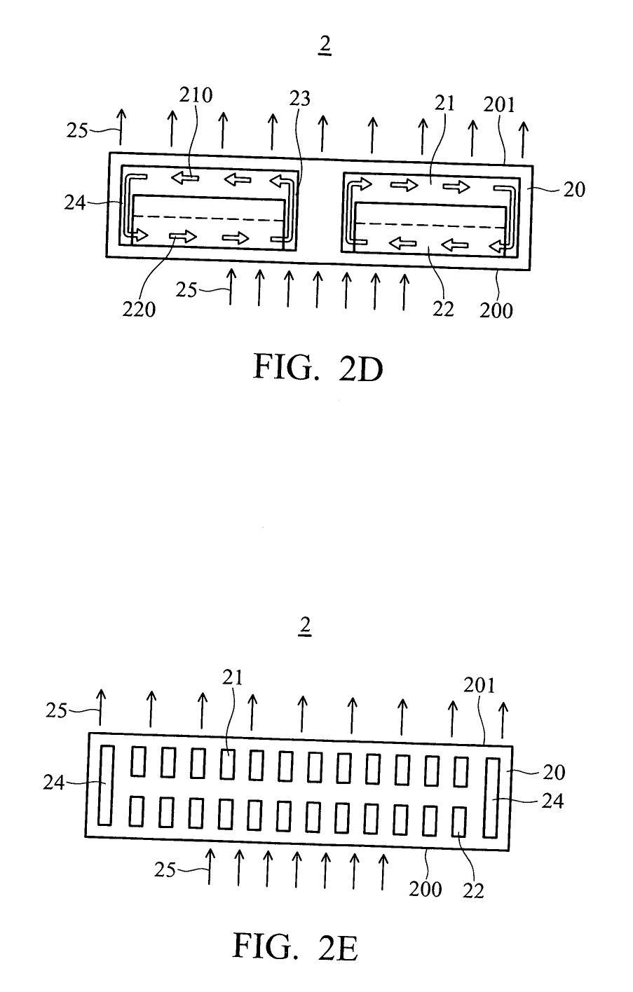

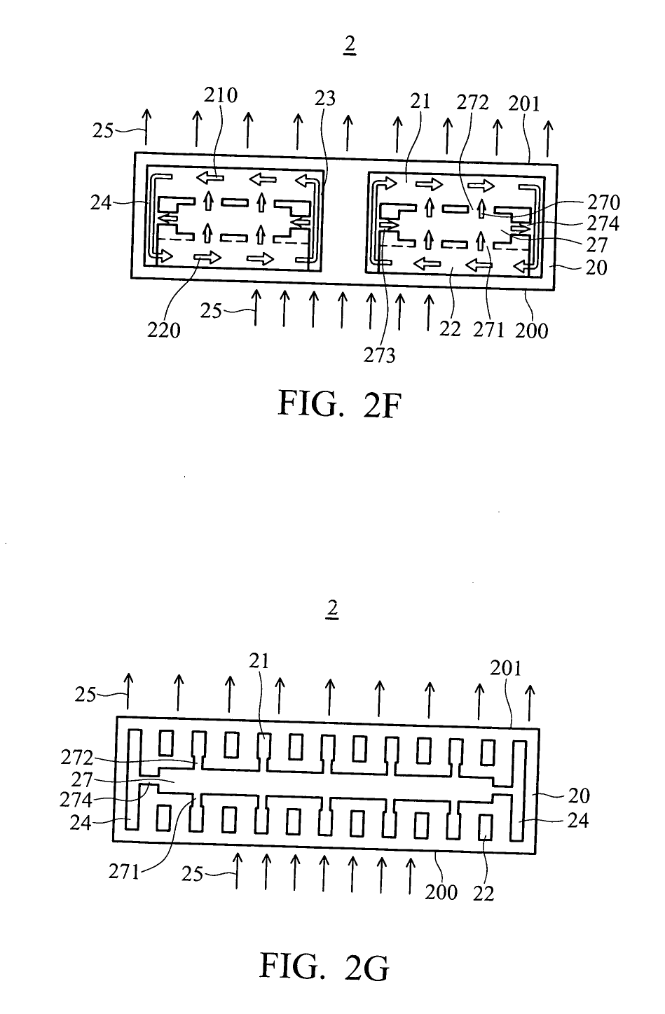

As shown in FIG. 2A, in the first embodiment of the invention, a heat dissipation device 2 comprises a case 20, at least one heat dissipation path 21, at least one backflow path 22, a first link path 23, and a second link path 24, wherein the case may comprise metal or nonmetal materials and the heat dissipation path 21, the backflow path 22, the first link path 23, and the second link path 24 are disposed in the case 20 having working fluid therein. Moreover, the first link path 23 connects one end of the heat dissipation path 21 with one end of the backflow path 22. The second link path 24 connects the other end of the heat dissipation path 21 with the other end of the backflow path 22. As shown by arrows 210 and 220 in FIG. 2A, the working fluid flows through the backflow path 22, the first link path 23, the heat dissipation path 21, the second link path 24, and finally back to the backflow path 22. In FIG. 2A, the heat dissipation path 21 is shown in real lines and the backflow path 22 is shown in dotted lines. Thus, it can be seen that the heat dissipation path 21 and the backflow path 22 are at different height levels. Namely, a plane formed by the heat dissipation path 21 is different from that formed by the backflow path 22.

FIG. 2B is a side-viewed cross section along the heat dissipation path 21 of the heat dissipation device 2. The backflow path 22 of the heat dissipation device 2 is disposed in the vicinity of a first portion 200 of the case 20 and the first portion 200 may be disposed in the vicinity of a heat source (not shown); the heat dissipation path 21 is disposed in the vicinity of a second portion 201 of the case 20 and the second portion 201 may be disposed in a location with relatively lower temperature than the heat source. Accordingly, when flowing along backflow path 22, the working fluid absorbs heat dissipated by the heat source. Further, the working fluid flows along the heat dissipation path 21 through a first link path 23, conducting heat through the second portion 201 of the case 20, and finally returning to the backflow path 22 through the second link path 24. Through the cycle, heat is conducted away in the direction as shown by arrow 25.

FIG. 2C is a cross-section along A-A′ line in FIG. 2A. The plane formed by the heat dissipation path 21 is different from that formed by the backflow path 22. Moreover, in this embodiment, the bottom of the plane formed by the heat dissipation path 21 and the top of the plane formed by the backflow path 22 are precisely located at the same height level such that the fabrication method of the heat dissipation device is therefore simplified. However, the invention is not limited thereto. It will work when the heat dissipation path 21 and the backflow path 22 disposed at different height levels; even the bottom of the plane of the heat dissipation path 21 is lower than the top of plane of the backflow path 22. Furthermore, as shown in FIG. 2D and FIG. 2E, when the bottom of the plane formed by the heat dissipation path 21 is higher than the top of the plane formed by the backflow path 22, the heat dissipation path 21 and the backflow path 22 are completely isolated and their arrangement density may be increased to dissipate more heat per unit area. In this invention, the heat dissipation path 21 and the backflow path 22 are not linked except by their ends through the first link path 23 and the second link path 24.

Additionally, the heat dissipation device 2 further comprises a dissipation space 27, as shown in FIG. 2F-2G. The dissipation space 27 comprises a plurality of first dissipation paths 272 linked to the heat dissipation path 21 and a plurality of second dissipation paths 271 linked to the backflow path 22. When circulating in the heat dissipation device 2, especially through the backflow path 22, the working fluid may absorb heat from the heat source to be vaporized. The vapor flows through the second dissipation paths 271 to the dissipation space 27, then through the first dissipation paths 272 to the heat dissipation path 21, dissipating heat via the heat dissipation path 21, and flowing back along the backflow path 22 through the second link path 24. An alternative design of the dissipation space 27 may further comprise a plurality of third dissipation paths 273 linked to the first link path 23 and a plurality of fourth dissipation paths 274 linked to the second link path 24 such that the dissipation paths of the steamed working fluid are increased, thereby improving heat dissipation efficiency of the heat dissipation device 2 of the invention.

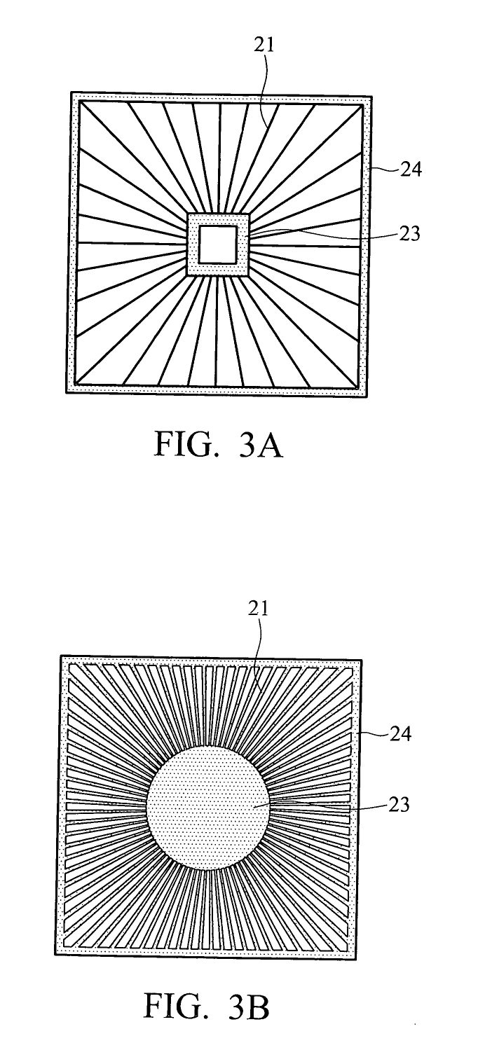

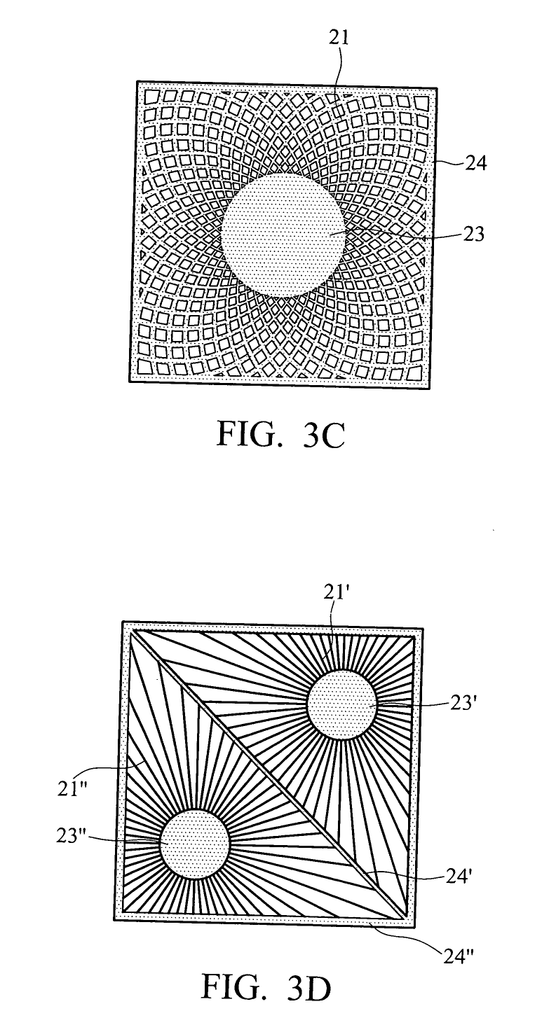

In the mentioned embodiment, the plane formed by the heat dissipation path 21, as shown in FIG. 3A, is radial. Furthermore, the heat dissipation path 21 is radiated. Additionally, one end of the heat dissipation path 21 in the vicinity of center is connected to the first link path 23 and the other end in the vicinity of outside is connected to the second link path 24. Preferably, the second link path 24 is annularly disposed outside the first link path 23 and the plane formed by the backflow path 22 may follow that of the heat dissipation path 21; however, the shape of the plane of the heat dissipation path 21 is not limited. As shown in FIGS. 3B and 3C, the shape may be an arc shape, or an alternate shape. Further, referring to FIG. 3D, the heat dissipation device 2 ma, include two groups of heat dissipation paths 21′ and 21″, two first link paths 23′ and 23″, and two second link paths 24′ and 24″ coordinating with each other to form two heat dissipation areas. Like the other embodiments, the heat dissipation device 2 with two-group arrangement provides the same heat dissipation effect and the distribution of the backflow paths is the same as that of the heat dissipation paths.

Accordingly, the heat dissipation device 2 of the first embodiment of the invention comprises heat dissipation path 21 enabling the working fluid to circulate therein and along the backflow path 22. Moreover, the heat dissipation path 21 and the backflow path 22 are located at different height levels such that the working fluid dissipates heat in the heat dissipation path 21 and absorb heat in backflow path 22 without producing turbulence. Hence, heat dissipation efficiency is increased. Additionally, the working fluid of the heat dissipation device does not require changing states between a gas state and a liquid state. Thus, the working fluid completely maintains state (gas or liquid) such that the selectivity of the working fluid is wider and more convenient for industry to use.

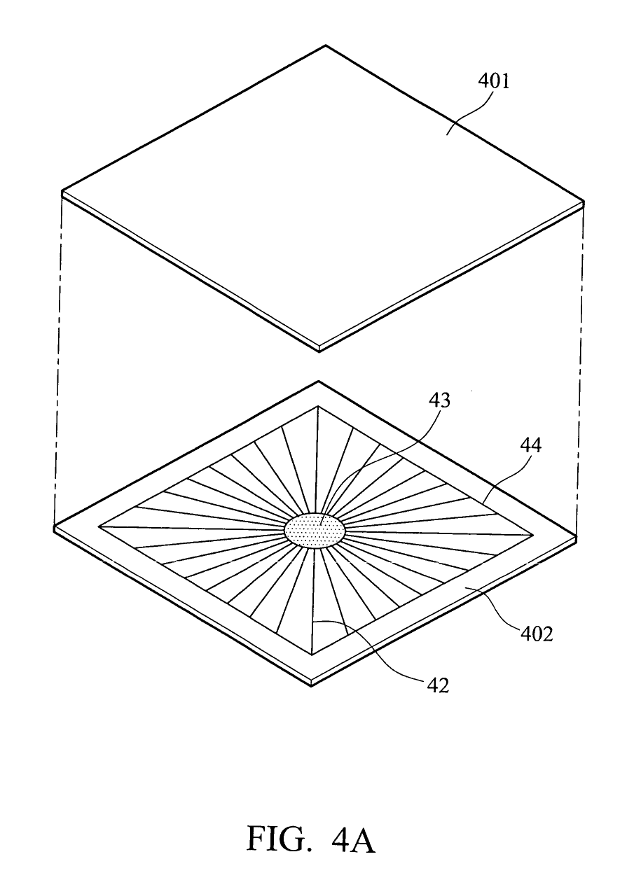

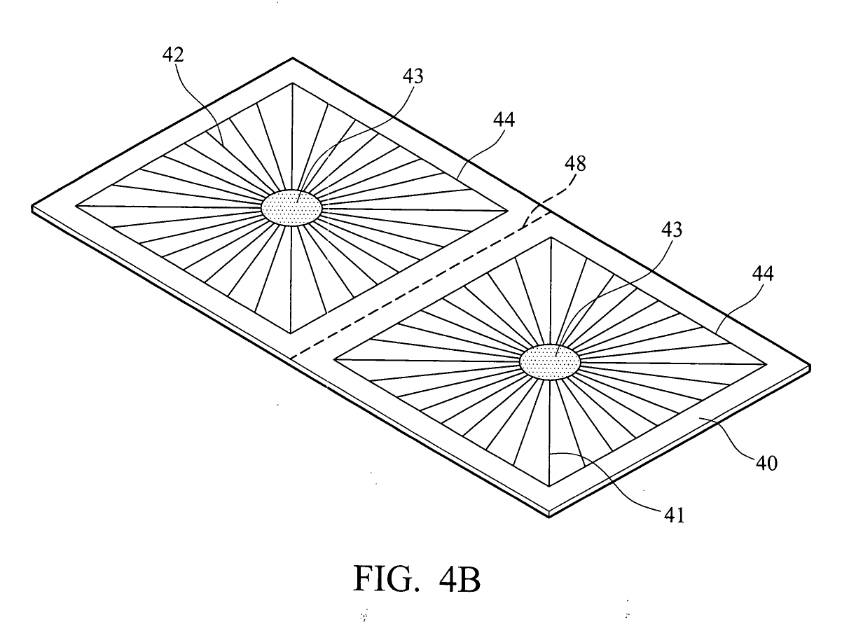

The invention provides a method for fabricating a heat dissipation device, as shown in FIG. 4A, comprising forming a heat dissipation path (not shown), a first link path (not shown), and a second link path (not shown) on a first board 401, forming a backflow path 42, a first link path 43, and a second link path 44 on a second board 402, and final gluing and fixing of the side of the first board 401 having the heat dissipation path with the side of the second board 402 having the backflow path 42 to form a heat dissipation device 2, wherein the method conducted to form the heat dissipation path, the backflow path 42, the first link path 43, and the second link path 44 is accomplished by molding, punching, MEMS, etching, or other conventional means such as drilling, milling, digging or a combination thereof. Moreover, any means to form a recession on the first board 401 or a groove on the second board 402 can be adopted. While the first board 401 and the second board 402 are glued together, the heat dissipation path 41 and the backflow path 42 are interactively independent.

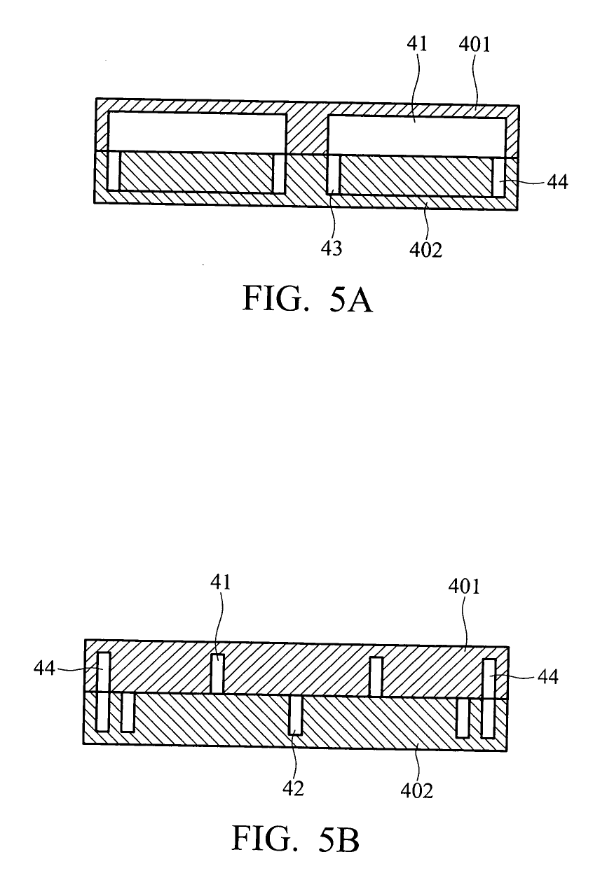

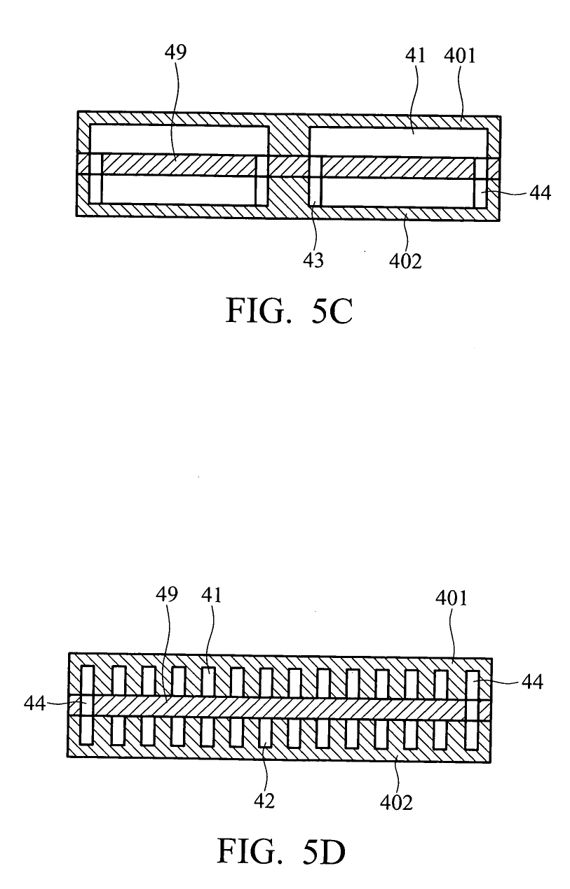

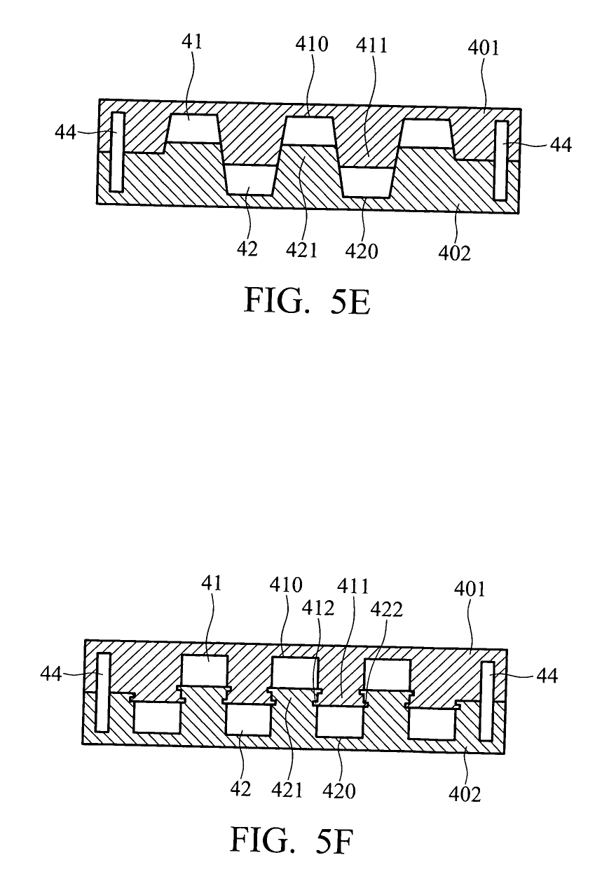

Please refer to FIGS. 5A and 5B. The first board 401 having the heat dissipation path 41 and the second board having the backflow path 42 are glued together, wherein it is obvious that only two ends of the heat dissipation path 41 and the backflow path 42 are connected to form the heat dissipation device 2 illustrated in FIG. 2B and FIG. 2C. Furthermore, before the step of gluing the first board 401 and the second board 402, a partition 49 is disposed between the heat dissipation path 41 and the backflow path 42. After gluing the boards, even utilizing the same distribution, the heat dissipation path 41 and the backflow path 42, as shown in FIGS. 5C and 5D, are still interactively independent because of the partition 49, forming the heat dissipation device 2 illustrated in FIG. 2D and FIG. 2E.

Further, referring to FIG. 5E, the heat dissipation path 41 of the first board 401 comprises a plurality of recessions 410 and a plurality of protrusions 411 arranged in sequence and the backflow path 42 of the second board 402 also comprises a plurality of recessions 420 and a plurality of protrusions 421 arranged in sequence, wherein the recessions 410 correspond to the protrusions 421 and the recessions 420 correspond to the protrusions 411. Preferably, in this embodiment, the shapes of the recessions 410,420 and the shapes of the protrusions 411,421 are trapezoid, rectangle, triangular, circular, or irregular. When the first board 401 and the second board 402 are glued together, the protrusions 411 of the heat dissipation path 41 are received in the corresponding recessions 420 of the backflow path 42 and the protrusions 421 of the backflow path 42 are received in the corresponding recessions 410 of the heat dissipation path 41 in order to form the heat dissipation device 2.

As shown in FIG. 5F, the protrusions 411 of the first board 401 comprises hooks 412 and the recessions 420 of the second board 402 comprises grooves 422. When the protrusions 411 of the heat dissipation path 41 are received in the corresponding recessions 420 of the backflow path 42, the hook 412 joins the groove 422 in order to glue and fix the first board 401 and the second board 402 together. Similarly, The protrusions 421 of the second board 402 comprise hooks (not shown) and the recessions 410 of the first board 401 comprise grooves (not shown); alternatively, the first board 401 and the second board 402 may comprise the same structure to approach the same result.

The invention provides another method for fabricating a heat dissipation device comprising providing a board 40, forming a heat dissipation path 41, a backflow path 42, a first link path 43, and a second link path 44 on the board, wherein the heat dissipation path 41, the backflow path 42, the first link path 43, and the second link path 44 are formed by molding, punching, MEMS, etching, or other conventional means such as drilling, milling, digging or a combination thereof. Moreover, any means to form a recession portion on the board 40 can be adopted to produce the heat dissipation path 41, the backflow path 42, the first link path 43, and the second link path 44. Then, the bending and fixing the board 40 is applied in accordance with a bending line 48 to form a heat dissipation device, wherein after the board is bent and glued, the distribution of the heat dissipation path 41 and the backflow path 42 is the same as that mentioned before.

The above-mentioned method of fabricating a heat dissipation device is not limited thereto. The heat dissipation device is workable if the structure and the feature are similar to the embodiment of the above-mentioned disclosed.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat dissipation device, comprising:
a case comprising a first portion, and a second portion;
a heat dissipation path disposed in the vicinity of the second portion of the case;
a backflow path disposed in the vicinity of the first portion of the case;
a first link path connecting one end of the heat dissipation path with one end of the backflow path; and
a second link path connecting the other end of the heat dissipation path with the other end of the backflow path,
wherein the case contains a working fluid; the working fluid absorbs heat while circulating along the backflow path and dissipates heat while circulating along the heat dissipation path.

2. The heat dissipation device as claimed in claim 1, wherein a plane formed by the heat dissipation path is different from that formed by the backflow path.

3. The heat dissipation device as claimed in claim 1, further comprising a partition disposed between the heat dissipation path and the backflow path.

4. The heat dissipation device as claimed in claim 3, wherein the partition comprises a dissipation space and the dissipation space comprises a first dissipation path connected with the heat dissipation path as well as a second dissipation path connected with the backflow path.

5. The heat dissipation device as claimed in claim 3, wherein the partition comprises a dissipation space and the dissipation space comprises a third dissipation path connected with the first link path as well as a fourth dissipation path connected with the second link path.

6. The heat dissipation device as claimed in claim 1, wherein the second link path is annularly disposed outside the first link path.

7. The heat dissipation device as claimed in claim 1, wherein the working fluid flows sequentially through the backflow path, the first link path, the heat dissipation path, the second link path and finally back to the backflow path.

8. The heat dissipation device as claimed in claim 1, wherein the case comprises a first board and a second board, wherein the heat dissipation path disposed in the second board comprises a plurality of recessions and a plurality of protrusions arranged in sequence and the backflow path disposed in the first board further comprises a plurality of recessions and a plurality of protrusions arranged in sequence, wherein the shape of the recessions are complementary to that of the protrusions.

9. The heat dissipation device as claimed in claim 8, wherein the protrusions comprise hooks and the recessions comprise grooves such that the protrusions of the heat dissipation path are received in the corresponding recessions of the backflow path and the hooks of the protrusion portions join the grooves of the recession portions.

10. The heat dissipation device as claimed in claim 8, wherein the protrusions comprise hooks and the recessions comprise grooves such that the protrusions of the backflow path are received in the corresponding recessions of the heat dissipation path and the hooks of the protrusions join the grooves of the recessions.

11. The heat dissipation device as claimed in claim 1, wherein the distribution of the heat dissipation path or the backflow path comprises radial, arc, or alternate shape.

12. The heat dissipation device as claimed in claim 1, wherein the second portion comprises a heat sink.

13. A method for fabricating a heat dissipation device, comprising:
forming a heat dissipation path, a backflow path, a first link path, and a second link path on a board; and
bending and fixing the board via a bending line disposed on the board to form a heat dissipation device.

14. The method as claimed in claim 13, wherein the heat dissipation path comprises a plurality of recessions and a plurality of protrusions arranged in sequence and the backflow path further comprises a plurality of recessions and a plurality of protrusions arranged in sequence; the shapes of the recessions are complementary to those of the protrusions; when the board is bent, the protrusions of the heat dissipation path are received in the corresponding recessions of the backflow path and the protrusions of the backflow path are received in the corresponding recessions of the heat dissipation path in order to bend and fix the board to form the heat dissipation device.

15. The method as claimed in claim 13, wherein after bending the board, the heat dissipation path and the backflow path are interactively independent.

16. The method as claimed in claim 13, wherein before bending and fixing the board, a partition disposed between the heat dissipation path and the backflow path;
after bending and fixing the board, the heat dissipation path and the backflow path are interactively independent.

17. The method as claimed in claim 13, wherein the heat dissipation path, the backflow path, the first link path, and the second link path are formed simultaneously.

18. The method as claimed in claim 13, wherein the method conducted to form the heat dissipation path, the backflow path, the first link path, and the second link path is formed by molding, punching, MEMS, etching, drilling, milling, digging or a combination thereof.

19. A method for fabricating a heat dissipation device, comprising:
forming a heat dissipation path, a first link path, and a second link path on a first board;
forming a backflow path, a first link path, and a second link path on a second board; and
gluing and fixing the side of the first board having the heat dissipation path with the side of the second board having the backflow path to form a heat dissipation device.

20. The method as claimed in claim 19, wherein the heat dissipation path comprises a plurality of recessions and a plurality of protrusions arranged in sequence and the backflow path further comprises a plurality of recessions and a plurality of protrusions arranged in sequence; the shapes of the recessions are complementary to those of the protrusions; while the board is bent, the protrusions of the heat dissipation path are received in the corresponding recessions of the backflow path and the protrusions of the backflow path are received in the corresponding recessions of the heat dissipation path in order to bend and fix the board to form the heat dissipation device.

21. The method as claimed in claim 19, wherein when the boards are glued together, the heat dissipation path and the backflow path are interactively independent.

22. The method as claimed in claim 19, wherein before bending and fixing the board, a partition is disposed between the heat dissipation path and the backflow path; after bending and fixing the board, the heat dissipation path and the backflow path are interactively independent.

23. The method as claimed in claim 19, wherein the method conducted to form the heat dissipation path, the backflow path, the first link path, and the second link path is formed by molding, punching, MEMS, etching, drilling, milling, digging or a combination thereof.
